(19) United States
(12) Patent Application Publication
(10) Pub. No.: US 2024/0038488 A1
(43) Pub. Date: Feb. 1, 2024

(54) CRYOGENIC ELECTRON MICROSCOPY FULLY AUTOMATED ACQUISITION FOR SINGLE PARTICLE AND TOMOGRAPHY

(71) Applicant: Health Technology Innovations, Inc., Portland, OR (US)

(72) Inventors: Narasimha KUMAR, Portland, OR (US); Elliot Marshall GRAY, Portland, OR (US); Charles Alexandro RICE, Portland, OR (US)

(21) Appl. No.: 18/363,530

(22) Filed: Aug. 1, 2023

Related U.S. Application Data
(60) Provisional application No. 63/370,066, filed on Aug. 1, 2022.

(51) Int. Cl. H01J 37/26; G06T 17/00; G02B 21/36; G02B 21/02

(52) U.S. Cl. CPC H01J 37/261; G06T 17/00; G02B 21/367; G02B 21/025; G06T 2207/10056; H01J 2237/223

(57) ABSTRACT

Described herein are techniques for identifying biological structures using a cryogenic electron microscopy (cryo-EM). In some embodiments, first images captured at a first magnification level may be received depicting cryo-EM grid units. Using a first ML model, one or more cryo-EM grid units may be detected based on the first images. Second images of each cryo-EM grid unit captured at a second magnification level may be received and, using a second ML model, one or more apertures within the cryo-EM grid may be detected based on the second images. One or more images captured at a third magnification level of depicting at least one of ice or a biological structure suspended within each aperture may be received and a Fourier transformation may be generated. Using a third ML model, at least one image depicting the biological structure from the images may be identified based on the Fourier transformations.

### CROSS-REFERENCE TO RELATED APPLICATION

This application claims priority to U.S. Provisional Application No. 63/370,066, filed on Aug. 1, 2022, and entitled “CRYOGENIC ELECTRON MICROSCOPY FULLY AUTOMATED ACQUISITION FOR SINGLE PARTICLE TOMOGRAPHY,” the disclosure of which has been incorporated herein by reference in its entirety.

### BACKGROUND

Structural biology is the science of accurately identifying the structures of biological molecules, such as proteins and viruses. Biologists, chemists, and drug discoverers need these detailed high-resolution structures to make further innovations possible, such as identifying the lead drug candidates for treatment of an illnesses. Structure-based drug discovery is a major part of pharmaceutical innovations today.

For the past several decades, biological structures were determined using tools like X-Ray Crystallography and Nuclear Magnetic Resonance (NMR). Though these methods have been effective, they have shortcomings. For example, some biological molecules cannot be crystallized, or they exhibit variations (called heterogeneity). Besides, these legacy techniques could not meet the higher resolutions demanded by today's drug research. Cryogenic Electron Microscopy (cryo-EM) addresses these issues effectively.

Cryo-EM is quickly becoming an impactful tool for structural biology today. For example, the SARS-CoV-2 virus, which causes Covid-19, has been analyzed extensively using cryo-EM technology. In cryo-EM, biological samples are frozen and placed on grids of different types (carbon, gold, etc.) for imaging. These grids contain “squares,” and each square may include one or more “holes.” Within the “holes,” ice, biologic structures (e.g., proteins), and the like may be suspended. Images are collected of the grids and squares are selected from those images. Images may also be obtained depicting holes for each square, and holes are selected from these images. Afterword, micrographs of the selected holes are obtained and analyzed to select particles for downstream data processing and analysis into 3D structures. An accurate 3D model of the structure is needed to accelerate identification of lead candidates for drug discovery. However, collecting good cryo-EM data is difficult. The data collection time is expensive since microscope time is expensive (for example, some cost several million dollars). Further complicating matters is the microscopes need for specialized housing facilities to avoid/reduce vibrations. Additionally, existing cryo-EM methods are manual. Because of this, a trained scientist must be present while the data is being collected to monitor the progress and adjust settings. Not only are these staffing requirements expensive, each individual can introduce their own bias to the collected data, thereby impacting the results.

Further still, a significant amount of the collected data collected can be of poor quality. The poor quality data can reduce the trust and accuracy of the resulting 3D model of the biological structures derived from this data. This results in a loss of productivity, and thus monetary loss as well.

### SUMMARY

Disclosed are systems and methods for identifying biological structures depicted within an image captured using cryogenic electron microscopy. The biological structures may be identified using a set of machine learning models. For example, a first machine learning model may be trained to analyze low-magnification images of a grid. The grid may include squares, and the squares may include one or more holes. Within the holes, ice and/or the biological structures may be suspended. The first machine learning model may detect which of the squares are “good,” and can be used for further analysis. Images of the “good squares” may be captured at a medium-magnification level and input to a second machine learning model. The second machine learning model may be trained to detect any holes present within a “good square,” and determine which of the holes are “good.” Images of the “good holes” may be captured at a high-magnification level. These images, also called “micrographs,” can then be analyzed to identify the biological structures. In one or more examples, a Fourier transformation may be performed to the micrographs. A third machine learning model may be trained to analyze the Fourier transforms of the images of the micrographs to determine which of the micrographs are “good.” Using the “good micrographs,” at least one micrograph may be identified that depict the biological structures. These micrographs can then be used for 3D modeling of the biological structure, which can be used to further aid in the drug discovery process.

The embodiments disclosed above are only examples, and the scope of this disclosure is not limited to them. Particular embodiments may include all, some, or none of the components, elements, features, functions, operations, or steps of the embodiments disclosed above.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates an example system for implementing cryogenic electron microscopy data collection and analysis, in accordance with various embodiments.

FIG. 2 illustrates a pictorial view of the image processing and image acquisition steps, in accordance with various embodiments.

FIGS. 3A-3C illustrate images captured using electron microscopy techniques at various magnification levels, in accordance with various embodiments.

FIG. 4 is a flowchart illustrating another example method for cryogenic electron microscopy data collection and analysis, in accordance with various embodiments.

FIG. 5 illustrates an example of squares of a grid, in accordance with various embodiments.

FIG. 6 illustrates an example of a detected hole within a square, in accordance with various embodiments.

FIG. 7 illustrates an example of federated learning with multiple collaborators, in accordance with various embodiments.

FIG. 8 illustrates an example database schematic, in accordance with various embodiments.

FIG. 9 illustrates an example cloud approach, in accordance with various embodiments.

FIG. 10 illustrates example micrographs and their corresponding Fourier Transforms for evaluating micrograph quality, in accordance with various embodiments.

FIG. 11 illustrates an example architecture of system described herein, in accordance with various embodiments.

FIG. 12 illustrates a flowchart of an example method for training a machine learning via a semi-supervised approach, in accordance with various embodiments.

FIG. 13 illustrates an example flowchart of a method for performing data analysis by analyzing a subset at a time and deciding on the next subset for analysis, in accordance with various embodiments.

FIG. 14 illustrates an example flowchart of a method for selecting on-the-fly data acquisition targets based on a quality of the current data, in accordance with various embodiments.

FIG. 15 illustrates an example computer system used to implement one or more embodiments.

### DETAILED DESCRIPTION

Particular embodiments disclosed herein may be designed to address specific problems or omissions in the current state of the art. For example, described herein are embodiments relating to automation of data collection for cryogenic electron microscopy (cryo-EM). As another example, described herein are embodiments for generating an accurate 3D model of biological structures to improve an identification process for drug discovery candidates.

Cryo-EM has emerged as an impactful, exciting, and essential image and data processing tool for use by structural biologists, drug discovery scientists, and life science researchers. Recent advances in electron microscopes and software technologies have allowed detailed characterization and study of sensitive biological molecules in near-native states at atomic scale. The recognition of cryo-EM's innovation and capabilities is evident by recent momentum in the field. For example, the Protein Data Bank reported, in 2020, 2,390 structures were solved using cryo-EM—a 65% jump over the previous year. In addition, cryo-EM has been one of the most widely used technique for solving structures surpassing NMR methods.

Cryo-EM's ability to elucidate 3D structures of previously uncharacterized, complex molecules has made it a powerful tool to define binding modes of novel compounds in protein targets, increase throughput for drug lead discovery or optimization, and shorten time to clinical trials for new drugs. Recently the SARSCoV-2 virus, which causes Covid-19, has been analyzed extensively using cryo-EM technology.

Pharmaceutical companies focused on rapid drug discovery and time to market are finding that, despite recent advances in cryo-EM technologies that are making new structural biology discoveries possible, there are still a host of challenges to address. The data acquisition rates are accelerating and starting to far exceed data processing rates and the ability of researchers to utilize images, thus creating a bottleneck. With electron microscopes capturing images at sub-Angstrom (Å) resolutions today, acquisition of exceptionally large amounts of data (e.g., nearly 1 Terabyte of data/minute) is common and processing this data is a huge challenge.

While some software tools have been created to improve image preprocessing and particle picking, other parts of the cryo-EM workflow are still laborious and inefficient. For 2D and 3D image classification steps, researchers are still faced with manually reviewing more than images per each microscope session. In some cases, researchers wait for weeks before software applications reach the 3D model stage and are finally able to assess the images as “good” or “bad.” Only then can they go back and manually adjust microscope settings to improve data collection quality and repeat the process again. This results in not only poor productivity, but diminished accuracy, and results can be biased depending on who is at the controls. There is a need for automation of these processes to remove manual steps and accelerate the time to final structures.

While some software solutions exist for parts of the cryo-EM workflow, they do not address critical steps effectively and still require manual settings as well as time consuming integration between different tools. There is no end-to-end automated solution, and projects can take weeks to arrive at a final structure. As a comparison, X-ray crystallography can typically provide results within hours or a few days.

Particular embodiments disclosed herein may provide one or more of the following technical improvements:

Automatically acquiring good data: As mentioned, automation can result in reduced (expensive) idle times. Good data allows for better structures, which greatly helps downstream steps in drug-discovery by better identifying the candidates.

Ease of use by allowing application integration: When implemented well, the techniques described herein allow for automated filtering of the model, which can enable customization per run. This ease of use can remove and/or minimize user involvement.

Automatically collecting more data than the typical manual operation, which is restricted due to user input and user fatigue. Larger data allows for improved analysis later by accumulating a better set of good data.

Machine Learning, such as semi-supervised learning, allows updates to provide improved target identification and hence improved data collection over time.

Federated Learning allows for customization of the machine learning models for a given user, and allows for collaborative training/learning making the machine learning models more robust.

The database schema allows for better tracking of data between runs, sessions, grids, etc., making it easy to mine and use.

Particular embodiments disclosed herein may be implemented using one or more example architectures.

Particular embodiments may repeat one or more steps of the example process(es), where appropriate. Although this disclosure describes and illustrates particular steps of the example process(es) as occurring in a particular order, this disclosure contemplates any suitable steps of the example process(es) occurring in any suitable order. Moreover, although this disclosure describes and illustrates an example process, this disclosure contemplates any suitable process including any suitable steps, which may include all, some, or none of the steps of the example process(es), where appropriate. Furthermore, although this disclosure describes and illustrates particular components, devices, or systems carrying out particular steps of the example process(es), this disclosure contemplates any suitable combination of any suitable components, devices, or systems carrying out any suitable steps of the example process(es).

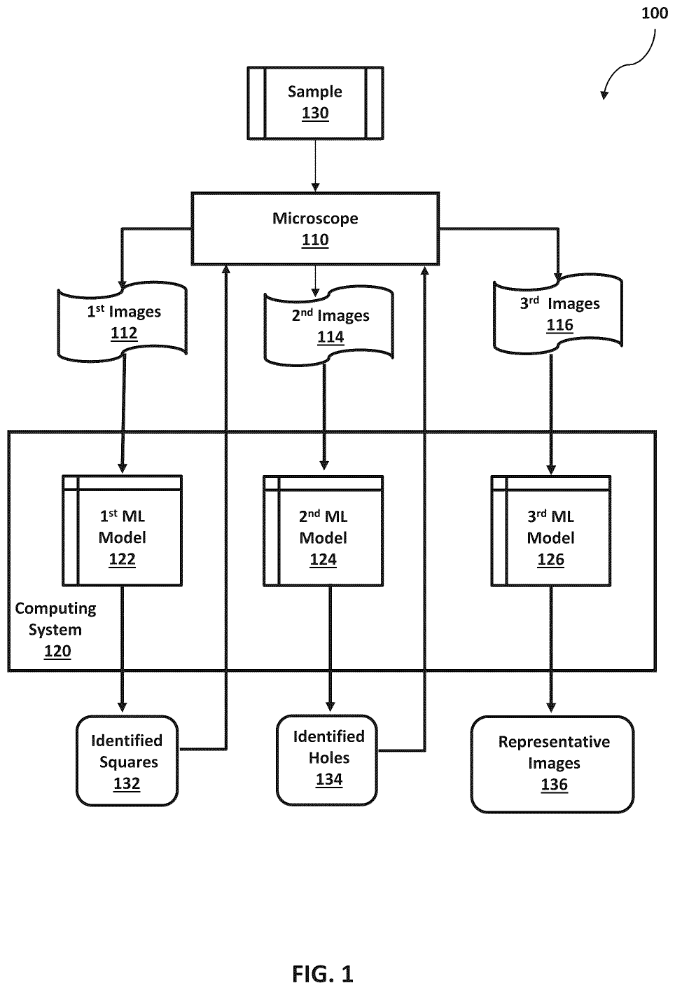

FIG. 1 illustrates an example system for implementing cryogenic electron microscopy data collection and analysis, in accordance with various embodiments. For instance, system 100 may include a microscope 110 and a computing system 120. Although a single instance of microscope 110 and computing system 120 is depicted within FIG. 1, additional instances of microscope 110 and/or computing system 120 may be included within system 100. Microscope 110 and computing system 120 may be configured to communicate data with one another, as well as, or alternatively, other devices. In some embodiments, microscope 110 is a microscope used to perform cryogenic electron microscopy. In some embodiments, computing system 120 is used to analyze data captured by microscope 110 (as well as other microscopes).

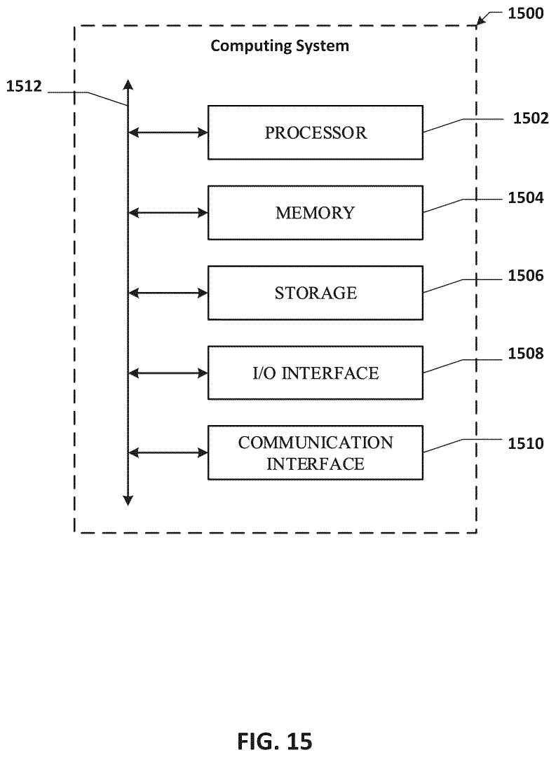

In some embodiments, computing system 120 may implement one or more machine learning models. Computing system 120 may execute these machine learning models utilizing one or more processing devices (e.g., computing system 1500 discussed below with respect to FIG. 15) that may include hardware (e.g., a general purpose processor, a graphic processing unit (GPU), an application-specific integrated circuit (ASIC), a system-on-chip (SoC), a microcontroller, a field-programmable gate array (FPGA), a central processing unit (CPU), an application processor (AP), a visual processing unit (VPU), a neural processing unit (NPU), a neural decision processor (NDP), a deep learning processor (DLP), a tensor processing unit (TPU), a neuromorphic processing unit (NPU), or any other processing device(s) that may be suitable for processing genomics data, proteomics data, metabolomics data, metagenomics data, transcriptomics data, or other omics data and making one or more decisions based thereon), software (e.g., instructions running/executing on one or more processors), firmware (e.g., microcode), or some combination thereof.

In some embodiments, microscope 110 may be Transmission Electron Microscope (TEM) hardware instrument (with its associated computing support). Microscope 110 may be configured to place the sample in cryogenic condition, control the electron beam in the microscope and direct an electron detection camera to capture the images. Microscope 110 can also support many parameters such as electron beam density, focus/defocus, angle of incidence etc., settable by the user. The user can prepare the sample in the appropriate way so it can be imaged.

In some embodiments, an image acquisition component may reside on microscope 110 and/or computing system 120. For simplicity, some operations may be discussed as occurring on computing system 120, however in some embodiments may include microscope 110 itself include one or more computing systems that are the same or similar to computing system 120, and thus operations performed by computing system 120 may alternatively be performed by microscope 110. The image acquisition component may include a software stack that controls microscope 110 and allows the user the collect data from the samples. In some embodiments, existing software may be utilized to implement a plug-in for the automatic imaging and quality assessment.

In some embodiments, the software stack may be used to process an acquired image and derive 3D structure information of a biological molecule. This software can de-noise the images and aggregate 2D projections into 3D models in an iterative fashion. This software can provide quantitative feedback to the image acquisition component, which can be used to further tune its algorithms.

In some embodiments, drug discovery may be performed using the 3D model output by the previous step to select drug candidates for discovery and diagnosis.

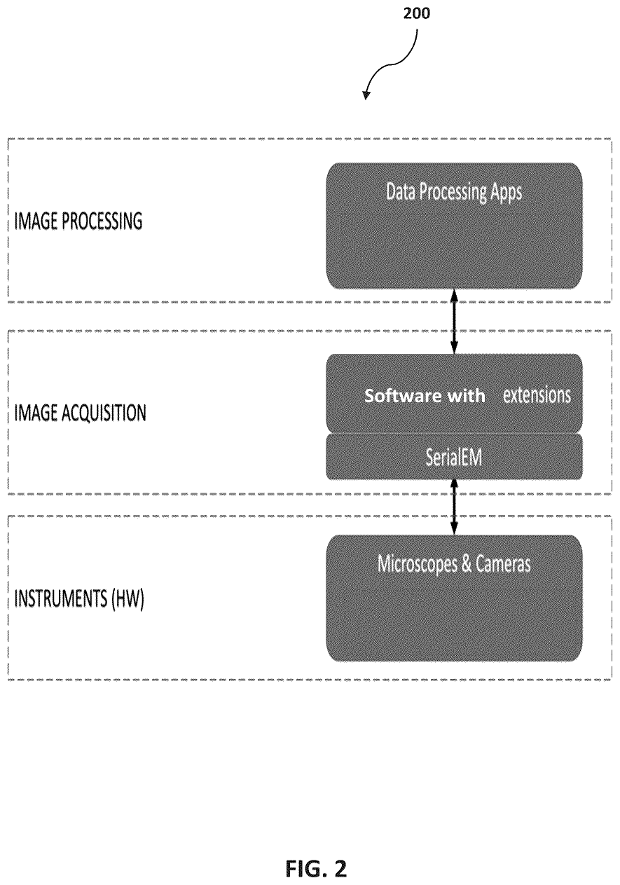

In some embodiments, the present disclosure may be implemented at the “image acquisition step,” as illustrated in view 200 of FIG. 2, and may be configured to adapt itself to internal assessments within that step and from the feedback from the “Image Processing” step of view 200. This architecture can easily adapt to use instruments from many vendors, acquisition stacks from many sources and data processing applications from many sources.

The deployment is flexible as well. The systems and methods described herein could be a tight bound plug-in extension to standard software. In this case, the software may reside on the same server/workstation, which can typically be computing system 120 connected to microscope 110.

The systems and methods described herein can be positioned on a separate server with a loosely coupled extension to the standard software. In this case, the systems and methods described herein can be on the same machine, or on a different machine in the enterprise, or on an on-prem server, or in the cloud. The options can have different costs (based on connectivity speeds, storage etc.).

Particular embodiments disclosed herein may be implemented in relation to different example use cases. These use cases include:

Integration into the image/data acquisition software supplied by the instrument maker. In this case, the software/algorithms and its usage can be embedded into their software.

A “plug-in” model. In this case, the user could obtain the model (e.g., the cryo-EM model described herein) and plug it into supported data acquisition software stacks.

A server (such as a software as a service (SaaS)) model: In this case, the software could be placed in a server to assist the data collection in real-time.

The architecture will allow for all these use cases.

Underlying foundational concepts and terms of art relied upon may relate to one or more of the following: software development, Artificial Intelligence/Machine Learning (AI/ML), mathematics/physics, and molecular biology, however additional fields may also be applicable and the aforementioned should not be construed as limiting.

In all example embodiments described herein, appropriate options, features, and system components may be provided to enable collection, storing, transmission, information security measures (e.g., encryption, authentication/authorization mechanisms), anonymization, pseudonymization, isolation, and aggregation of information in compliance with applicable laws, regulations, and rules. In all example embodiments described herein, appropriate options, features, and system components may be provided to enable protection of privacy for a specific individual, including by way of example and not limitation, generating a report regarding what personal information is being or has been collected and how it is being or will be used, enabling deletion or erasure of any personal information collected, and/or enabling control over the purpose for which any personal information collected is used.

In some embodiments, squares may be detected in a low-mag cryo-EM atlas such that a computer program can accurately direct the microscope to capture a medium-magnification image centered on that square.

As described herein, a “square” refers to one unit of a cryo-EM grid including holes within it. As described herein, a “grid” refers to a substrate with which cryo-EM samples are placed for imaging. As described herein, a “hole” refers to an aperture within the squares of the cryo-EM grid in which vitreous ice and protein is suspended. As described herein, an “atlas” refers to a montage of images taken at one or more magnification levels useful for target selection. The magnification levels may include low magnification, whereby squares are shown, and/or medium magnification, whereby holes are shown.

In some embodiments, holes may be detected in a medium-magnification cryo-EM atlas such that a computer program can accurately direct the microscope to capture a high-magnification micrograph centered at a specified place within the hole. As described herein, a “micrograph” refers to a high magnification image or images taken in cryo-EM.

In some embodiments, the quality of squares in a grid may be evaluated in a manner that correlates significantly and strongly with the same evaluation done by a human operator, and which leads to the identification of holes with high quality.

In some embodiments, the quality of holes in a square may be evaluated in a manner that correlates significantly and strongly with the same evaluation done by a human operator, and which consistently leads to the collection of high-magnification micrographs with high quality.

In some embodiments, the microscope may be directed to collect images (e.g., of medium- or high-magnification) using the target coordinates (e.g., locations specified relative to the center of holes) produced by the above way of hole detection.

In some embodiments, the quality of high-magnification micrographs may be evaluated to incorporate spatially resolved prediction (i.e., semantic segmentation), and identify at least some of the following objects within the micrographs: (i) protein molecules, along with some estimate of their spatial density (units per area), (ii) a quality of the ice, including: no ice, crystalline ice, eutectic ice, etc., (iii) the presence of contamination, such as, for example, ethane, (iv) the presence of physical distortion or damage to the carbon film substrate within the hole (e.g. folding, tearing), (v) the degree of defocus, (vi) the presence of protein aggregation, and (vii) the grid substrate.

In some embodiments, images may be transformed into a low-dimensional representation.

In some embodiments, a first transformation may be inverted so as to reconstruct the images from their low-dimensional representation with minimal loss of information.

In some embodiments, a similarity between images that have been transformed into the low-dimensional representation may be quantified (e.g., using a similarity metric).

In some embodiments, a process for selecting images for labeling that are dissimilar, in the low-dimensional space they have been transformed into, from the images that have previously been labeled.

In some embodiments, images may be displayed to the user with an interface that allows efficient annotation.

In some embodiments, a process for attributing special importance to a subset of the labeled images used during the training of the micrograph evaluation convolutional neural network (CNN) may be used such that they contribute greater weight to the loss function relative to the other labeled images in the training set. In some embodiments, transformers may be used.

In some embodiments, both holes and squares may be selected such that they incorporates both the estimates of square/hole quality produced by above-mentioned methods, as well as the estimates made by the above micrograph assessment method of the quality of micrographs that previously were collected.

The aforementioned processes may be developed using a Gaussian Process framework. The Gaussian process is a well-studied mathematical model, but its application to cryo-EM is novel. The use of micrograph assessments as a part of this choice process is also novel.

Returning to FIG. 1, system 100 may implement one or more steps to identify representative images captured at high-magnification levels, suitable for 3D biological structure modeling, from images captured at low-magnification levels.

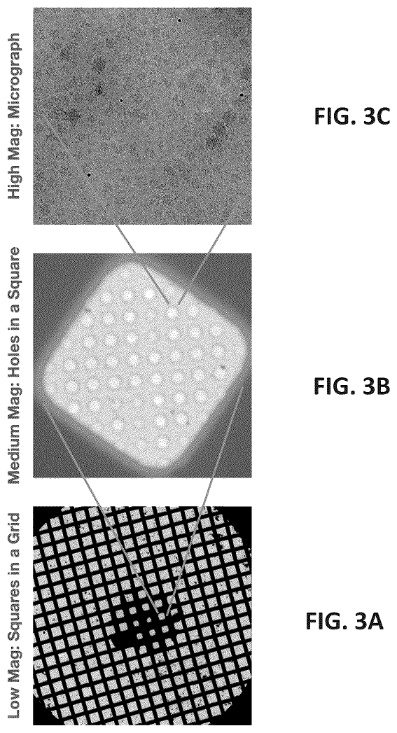

In some embodiments, computing system 120 may be configured to receive a first image montage comprising first images 112 captured at a first magnification level. In one or more examples, microscope 110 may be configured to capture first images 112 at the first magnification level based on an instruction. The instruction may specify the magnification level to be used for capturing first images 112, a location of where to focus to capture first images 112, or other information for capturing of first images 112. In one or more examples, the first image montage comprising first images 112 may depict a cryogenic electron microscopy grid comprising a plurality of cryogenic electron microscopy grid units. As an example, with reference to FIG. 3A, sample 130 being captured by microscope 110 may result in the images of a cryo-EM grid including holes within it. As described herein, a “grid” or “cryo-EM grid” refers to a substrate with which cryo-EM samples (e.g., samples 130) are placed for imaging. As described herein, a “square” refers to one unit (e.g., a cryogenic electron microscopy grid unit) of a cryo-EM grid including holes within it. The cryo-EM grid may itself include a plurality of cryo-EM grid units (e.g., squares).

In some embodiments, computing system 120 may be configured to execute a first machine learning (ML) model 122. The first image montage comprising first images 112 may be input to first ML model 122. First ML model 122 may be configured to detect one or more cryogenic electron microscopy grid units (e.g., squares) that satisfy a first quality condition based on the first image montage.

In some embodiments, computing system 120 may be configured to detect, using first ML model 122, one or more cryogenic electron microscopy units (e.g., identified squares 132) that satisfy a first quality condition. In one or more example, the cryo-EM grid units may use first ML model 122 to generate a first score indicating a quality of the cryogenic electron microscopy grid units. First ML model 122 may evaluate first images 122 to determine a first score for each square. Example images of a squares are illustrated in FIG. 3B. In one or more examples, the squares may be selected from the squares depicted within the cryo-EM grid (e.g., FIG. 3A).

In some embodiments, computing system 120 may be configured to select the one or more cryogenic electron microscopy grid units from the plurality of cryogenic electron microscopy grid units based on the first score being greater than or equal to a first quality threshold score. In one or more examples, the first quality threshold score may be a predefined value between 0.0 and 1.0. For example, the first quality threshold score may be 0.7 or greater, 0.8 or greater, 0.9 or greater, and the like.

In some embodiments, computing system 120 may be configured to train first ML model 122. In some embodiments, training first ML 122 may include obtaining a first plurality of training images captured at the first magnification level. The first plurality of training images each depict a cryogenic electron microscopy grid (e.g., FIG. 3A) comprising a plurality of cryogenic electron microscopy grid units. Each of the plurality of training images may also include metadata indicating a location and bounding box associated with each of the plurality of cryogenic electron microscopy grid units. Computing system 120 may further be configured to train the first machine learning model to identify cryogenic electron microscopy grid units based on the first plurality of training images. In some examples, first ML model 122 may comprise the trained first ML model. In one or more examples, the first ML model may be a convolutional neural network.

In some embodiments, the first machine learning model (e.g., first ML model 122) may be configured to determine a predicted location of a center of each of the cryogenic electron microscopy grid units within a corresponding training image from the first plurality of training images. The center for each grid may be stored in terms of pixel coordinates, physical coordinates of the image, or using other techniques. In some embodiments, the first machine learning model (e.g., first ML model 122) may be configured to determine a predicted boundary of each of the cryogenic electron microscopy grid units within a corresponding training image from the first plurality of training images. In some embodiments, the predicted boundary may comprise a bounding box enclosing a boundary of each square of the grid.

In some embodiments, training the first machine learning model may include inputting each of the first plurality of training images to the first machine learning model to obtain an output. The output may comprise a predicted location of a center of each of the cryogenic electron microscopy grid units. The output may, additionally or alternatively, comprise a predicted boundary of each of the cryogenic electron microscopy grid units. In some embodiments, computing system 120 may be configured to generate a comparison score. The comparison score may indicate how similar the predicted location is to the predetermined location, how similar the predicted boundary is to the predetermined boundary, or both. In some embodiments, computing system 120 may be configured to update a first set of parameters of the first machine learning model based on the comparisons. In some embodiments, the updating may be an iterative process. In some embodiments, the first machine learning model may be tested to ensure that it produces accurate results prior to deployment.

In some embodiments, computing system 120 may be configured to, for each of the one or more cryogenic electron microscopy grid units, receive a second image montage comprising second images of the cryogenic electron microscopy grid unit captured at a second magnification level. For example, computing system 120 may receive a second image montage comprising second images 114 captured by microscope 110. Second images 114 may be captured by microscope 110 at a second magnification level. In some embodiments, the second magnification level may comprise more magnification than the first magnification level used to capture first images 112. For example, the first magnification level may comprise 1×, 2×, 3×, etc., and the second magnification level may comprise 10×, 20×, 30×, etc. In some embodiments, computing system 120 may be configured to generate a second instruction to set the magnification level of microscope 110 to the second magnification level prior to the second image montage comprising second images 114 being captured.

In some embodiments, computing system 120 may be configured to execute a second machine learning (ML) model 124. The second image montage comprising second images 114 may be input to second ML model 124. Second ML model 124 may be configured to detect one or more apertures 134 within the cryogenic electron microscopy grid unit that satisfy a second quality condition based on the second image montage. As described herein, a “hole” refers to an aperture within the squares of the cryo-EM grid in which vitreous ice and protein are suspended. Identified holes 134 may be provided to microscope 110 with instructions to capture third images 116 (e.g., micrographs) captured at a third magnification level.

In some embodiments, computing system 120 may be configured to detect the one or more apertures that satisfy a second quality condition. In one or more example, second ML model 124 may generate a second score indicating a quality of the apertures depicted within a given cryo-EM unit (e.g., square). Second ML model 124 may evaluate second images 124 to determine a second score for each aperture. Example images of apertures within a square are illustrated in FIG. 3B. Computing system 120 may input second images 114 into second machine learning model 124 to obtain a second score indicating a likelihood that at least one of a biological structure suspended within each of a plurality of apertures depicted by second images 114. In some examples, ice may also be suspended within an aperture.

In some embodiments, from the plurality of apertures detected within the selected square, computing system 120 may be configured to selecting the one or more apertures that have a second score that is greater than or equal to a second quality threshold score. In one or more examples, the second quality threshold score may be a predefined value between 0.0 and 1.0. For example, the second quality threshold score may be 0.7 or greater, 0.8 or greater, 0.9 or greater, and the like. In one or more examples, the first quality threshold score may be the same or similar to the second quality threshold score.

In some embodiments, computing system 120 may be configured to train the second machine learning model. The training process, for example, may include obtaining a second plurality of training images captured at the second magnification level. For example, the second plurality of training images may each depict a cryogenic electron microscopy grid unit (e.g., a square) comprising a plurality of candidate apertures (e.g., holes). An example of a square including a plurality of holes is seen in FIG. 3B. In some embodiments, each of the second plurality of training images may also include metadata indicating a location and bounding box associated with each of the plurality of candidate apertures. The location and bounding box may comprise a predetermined location of a center of each candidate aperture (e.g., hole) and a predetermined bounding box or bounding shape enclosing the candidate aperture (e.g., hole).

In some embodiments, computing system 120 may be configured to train the second machine learning model to identify apertures based on the second plurality of training images. In some examples, second ML model 124 may comprise the trained second ML model. In one or more examples, the second ML model may be a convolutional neural network.

In some embodiments, the second machine learning model may be configured to determine a predicted location of a center of each of the apertures (e.g., holes) within a corresponding training image from the second plurality of training images. The center for each hole may be stored in terms of pixel coordinates, physical coordinates of the image, or using other techniques. Some embodiments include the second machine learning model being alternatively or additionally being configured to determine a predicted boundary of each of the apertures (e.g., holes) within a corresponding training image from the second plurality of training images. In some embodiments, the predicted boundary may comprise a bounding box enclosing a boundary of each hole of the square.

In some embodiments, training the second machine learning model may include inputting each of the second plurality of training images to the second machine learning model to obtain an output of a predicted location of a center of each of the apertures (e.g., the holes), or a predicted boundary of each of the apertures (e.g., the holes). In some embodiments, a comparison score may be generated using the second machine learning model. This comparison score may indicate how similar the predicted location is to the predetermined location, how similar the predicted boundary is to the predetermined boundary, or both. In some embodiments, a second set of parameters of the second machine learning model may be updated based on the comparisons. In some embodiments, the updating may be an iterative process. In some embodiments, the first machine learning model may be tested to ensure that it produces accurate results prior to deployment.

In some embodiments, computing system 120 may be configured to, for each of the one or more apertures, receive one or more images depicting at least one of ice or a biological structure suspended within the aperture captured at a third magnification level. For example, computing system 120 may receive third images 116 depicting sample 130 captured at the third magnification level. In one or more examples, the third magnification may comprise 100×, 200×, 300×, etc., and the second magnification level may comprise 10×, 20×, 30×, etc. In some embodiments, computing system 120 may be configured to generate a third instruction to set the magnification level of microscope 110 to the third magnification level prior to the one or more images (e.g., third images 116) being captured. Examples of an image of an aperture comprising biological structures at the third magnification level is illustrated in FIG. 3C.

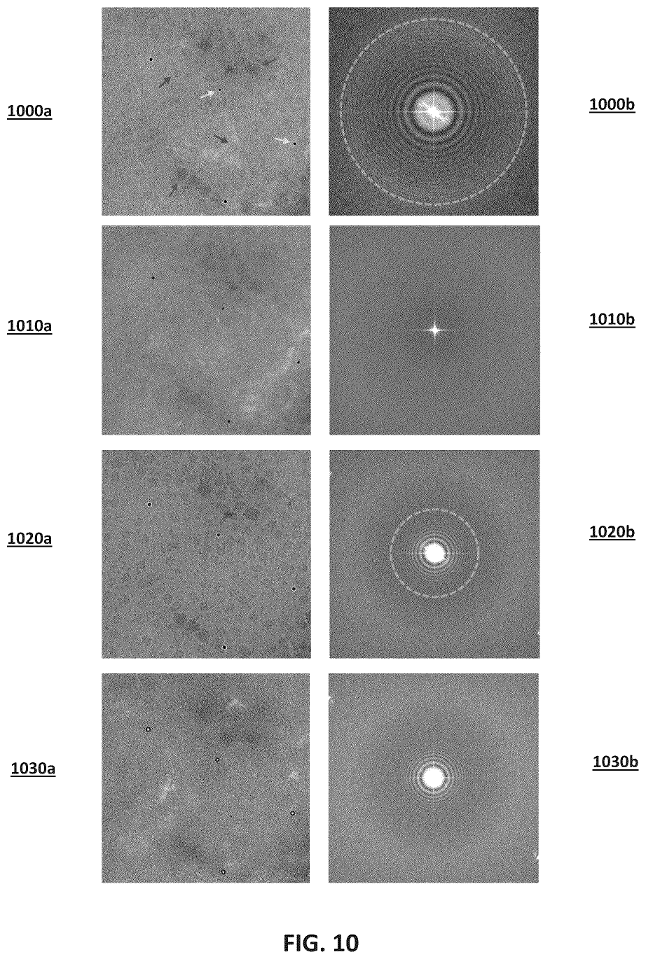

In some embodiments, computing system 120 may be configured to generate a Fourier transformation of each of the one or more images. As an example, with reference to FIG. 10, images 1000a-1030a represent micrographs of a selected aperture, and images 1000b-1030b represent a Fourier Transform of each corresponding micrograph.

In some embodiments, computing system 120 may be configured to identify, using a third machine learning model, at least one image depicting the biological structure from the one or more images based on the Fourier transformation of each of the one or more images. In some embodiments, a third score may be computed, which indicates a likelihood that the image of the Fourier transform is the same or similar to a reference image depicting a reference Fourier transform of a predetermined “good” micrograph. The representative image(s) (e.g., representative image 136) may be identified based on the third score.

In some embodiments, computing system 120 may be configured to generate a 3D representation of the biological structure (e.g., sample 130). In some embodiments, computing system 120 may be configured to perform one or more assays based on the 3D representation of the biologic structure for drug discovery evaluations.

In some embodiments, computing system 120 may be configured to train the third machine learning model. For instance, third ML model 126 may comprise the trained third machine learning model. In some embodiments, to train the third machine learning model, a third plurality of training images captured at the third magnification level may be obtained. In one or more examples, the third plurality of training images each depict an aperture from the one or more apertures. For example, a given training image may depict biological structures suspended within a hole. In one or more examples, each of the third plurality of training images may also comprise a first label or a second label. The first label may indicate whether the training image depicts a positive reference aperture, also referred to interchangeably as a “good micrograph.” The second label may indicate whether the training image depicts a negative reference aperture, also referred to interchangeably as a “bad micrograph.”

In some embodiments, computing system 120 may be configured to generate Fourier transform images representing a Fourier transform of each of the third plurality of training images. An image of a Fourier transform of an image, also referred to interchangeably as a Fourier transform image, may represent the input image, which is in the spatial domain, as an image in the frequency domain. For each of the Fourier transform images, computing system 120 may implement the third machine learning model to calculate a third score indicating a similarity between the Fourier transform image and an image of a Fourier transform of an image of a positive reference aperture. In some embodiments, from Fourier transform image, computing system 120 may be configured to selecting the at least one Fourier transform image having a third score that is greater than or equal to a third quality threshold score. In one or more examples, the third quality threshold score may be a predefined value between 0.0 and 1.0. For example, the third quality threshold score may be 0.7 or greater, 0.8 or greater, 0.9 or greater, and the like. In one or more examples, the third quality threshold score may be the same or similar to the first quality threshold score and/or the second quality threshold score.

In some embodiments, detecting the one or more cryogenic electron microscopy grid units (e.g., squares) may include identifying adjacent electron microscope grid units that are proximate to an already identified “good” grid unit.

As an example, identifying adjacent electron microscope grid units that are proximate to an already identified “good” grid unit may comprise computing system 120 selecting a first cryogenic electron microscopy grid unit (e.g., a square) of the plurality of cryogenic electron microscopy grid units (e.g., squares). Computing system 120 may be configured to generate a first score for the first cryogenic electron microscopy grid unit. In one or more examples, the first score may comprise an output from first ML model 122. In some embodiments, computing system 120 may determine that the first score for the first cryogenic electron microscopy grid unit is greater than or equal to a first threshold score. This may indicate that the evaluated square is a “good” square. In some embodiments, based on the determination that the first score for the first cryogenic electronic microscope grid unit is greater than or equal to the first threshold score, computing system 120 may be configured to select a second cryogenic electron microscopy grid unit of the plurality of cryogenic electron microscopy grid units, where the first cryogenic electron microscopy grid unit is located adjacent to the second cryogenic electron microscopy grid unit on the cryogenic electron microscopy grid. A second score for the second cryogenic electron microscopy grid unit may be calculated using the first machine learning model. In one or more examples, the second cryo-EM grid unit may also be selected based on the second score generated for the second cryo-EM grid unit being greater than or equal to the first threshold score.

Additionally, this process can also be used to select grids that are not near an identified “bad” grid unit. The goal of this technique is that good squares may be clustered near one another. Therefore, if a square is identified as being a “bad square,” then a “good square” is likely not located nearby. In some embodiments, computing system 120 may select a first cryogenic electron microscopy grid unit (e.g., a square) of the plurality of cryogenic electron microscopy grid units (e.g., squares). Computing system 120 may be configured to generate a first score for the first cryogenic electron microscopy grid unit. In one or more examples, the first score may comprise an output from first ML model 122. In some embodiments, computing system 120 may determine that the first score for the first cryogenic electron microscopy grid unit is less than a first threshold score. This may indicate that the evaluated square is a “bad square.” In some embodiments, based on the determination that the first score for the first cryogenic electronic microscope grid unit is less than the first threshold score, computing system 120 may be configured to select a second cryogenic electron microscopy grid unit of the plurality of cryogenic electron microscopy grid units. In some examples, where the first cryogenic electron microscopy grid unit is not located adjacent to the second cryogenic electron microscopy grid unit on the cryogenic electron microscopy grid. For example, the second square may be located at least a threshold distance (e.g., in units of pixels or spatial coordinates) from the first square. In some examples, the second square may be selected randomly from a subset of squares of the plurality of squares. The selected second square may be evaluated using the first machine learning model to determine whether the selected second square is a “good square.” This process may be repeated until a “good square” is detected, or until a predefined quantity of squares have been tested.

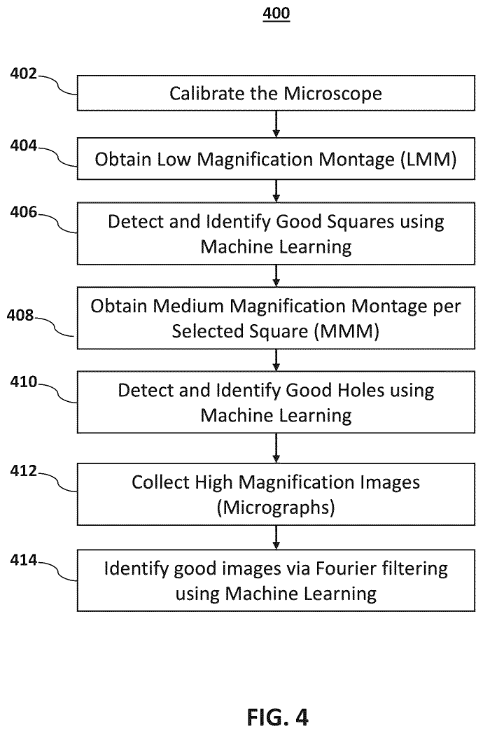

FIG. 4. is a flowchart illustrating another example method 400 for cryogenic electron microscopy data collection and analysis, in accordance with various embodiments. In some embodiments, method 400 may include automating one or more steps of the cryo-EM data collection and analysis process. For example, method 400 may begin at step 402. At step 402, an early calibration of the microscope (e.g., microscope 110) for the grid being used. At step 404, a low magnification montage (LMM) comprising first images captured at low magnification may be obtained. These images may be captured using microscope 110. At step 406, the squares forming the grid may be detected and evaluated so as to identify and select “good” squares in the LMM.

The identification and the selection of squares (e.g., step 406) may be performed using one or more machine learning models. For example, the machine learning models may be trained using a supervised approach, where the algorithm is trained by means of training data. In some cases, as detailed herein, existing data may be analyzed and used to generate data and label that data correctly. The labeling (also called annotation) may also be done with the help if experts in the field (e.g., a human-in-the-loop learning process).

At step 408, for every “good square,” method 400 can obtain a Medium Magnification Montages (MMM) comprising second images captured at medium magnification. These images may be captured using microscope 110. At step 410, holes included within the selected “good square” may be detected and evaluated so as to identify and select “good holes” in the MMM (e.g., step 408) for further imaging.

In some embodiments, at step 412, the targets from step 410 (e.g., “good holes”) may be used to obtain the High Magnification Images, also called Micrographs.

The identification and the selection of holes (e.g., step 414) may be performed using one or more machine learning models. For example, the machine learning models may be trained using a supervised approach, where the algorithm is trained by means of training data. In some cases, as detailed herein, existing data may be analyzed and used to generate data and label that data correctly. The labeling (also called annotation) may also be done with the help if experts in the field (e.g., a human-in-the-loop learning process).

The identification and the selection of holes is done in a similar way, using Machine Learning. This step is repeated for every selected square.

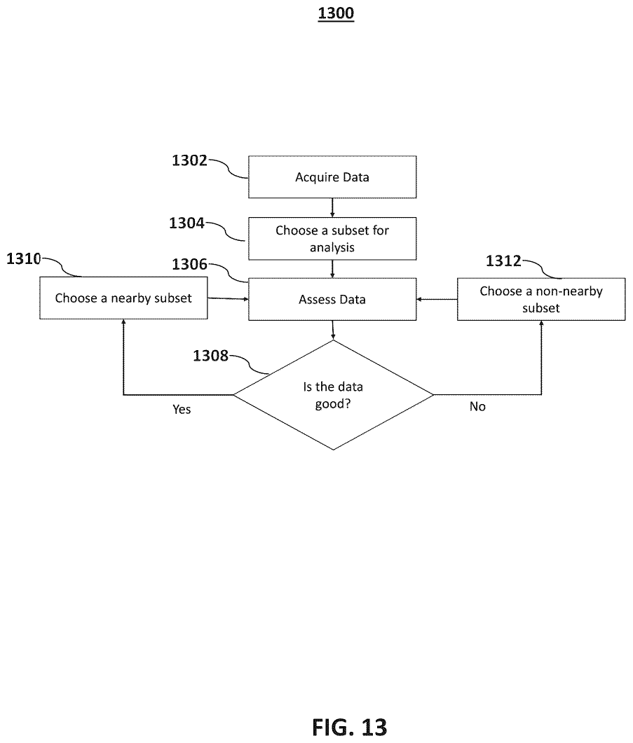

Additional training data will be collected to further refine the Machine Learning models (e.g., 1^{st}, 2^{nd} and/or 3^{rd} ML models 122, 124, and/or 126) for more accurate predictions for a larger diverse test dataset. To handle a significant large dataset, automated annotation techniques are used to expedite the labeling process, as described below with reference to FIG. 13.

In some embodiments, method 400 may include a step of identifying good images via Fourier filtering using machine learning. In one or more examples, for each micrograph, a Fourier transform image may be produced. A machine learning model (e.g., 3^{rd} ML model 126) may compare the produced Fourier transform image to reference Fourier transform images representing the Fourier transformation of an image of a hole that has been labeled as being representative.

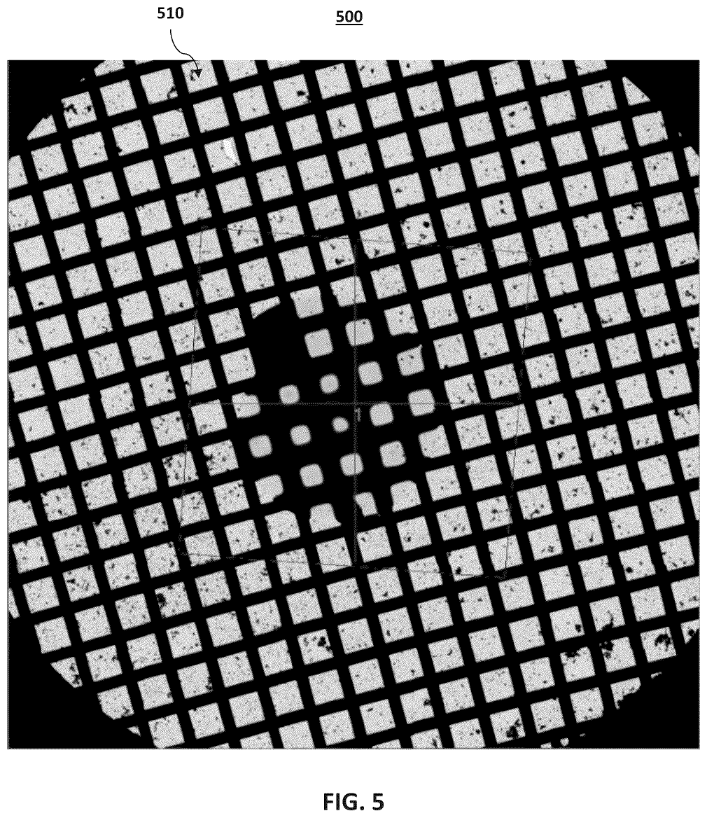

FIG. 5 illustrates an example image 500 of squares 510 of a grid, in accordance with various embodiments. In some embodiments, the first machine learning model (e.g., first ML model 122) may be configured to analyze first images 112 (which may include images similar to image 500) and identify one or more squares depicted therein. In some embodiments, the first machine learning model may identify a center of each square within image 500. In some embodiments, the first machine learning model may draw a bounding box around each square. Still further, the first machine learning model may number each of the squares or otherwise annotate image 500 to indicate which square is which.

In some embodiments, the first machine learning model may output a listing of all identified squares. The first machine learning model may organize the listing such that the squares are in size-order, which can help improve prediction accuracy by helping the user choose the relevant squares for the current analysis.

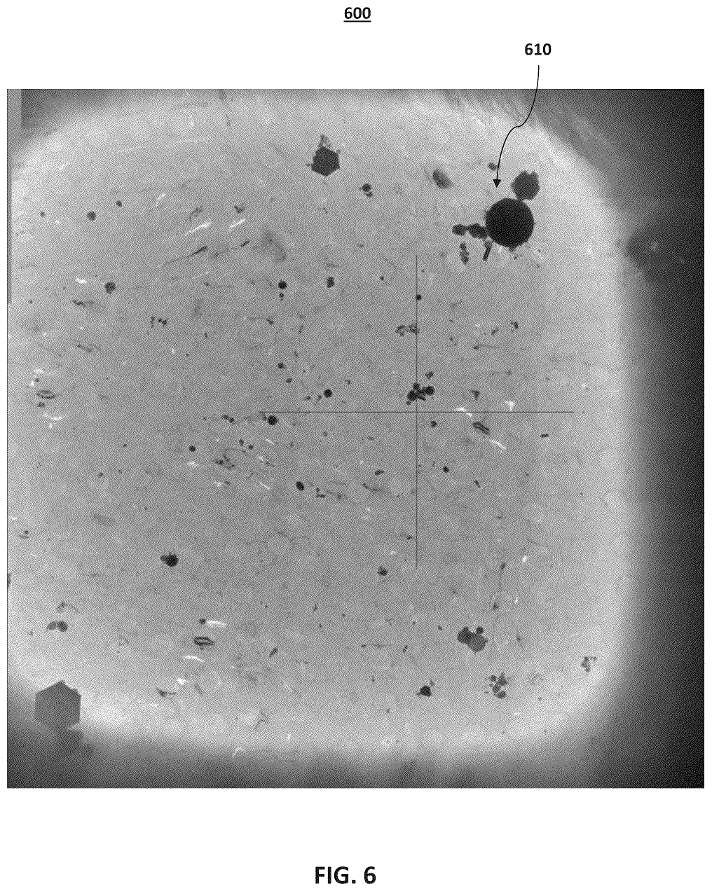

FIG. 6 illustrates an example image 600 of a square having one or more holes 610, in accordance with various embodiments. In some embodiments, holes 610 may be located near an edge of the square. For example, the holes may be located within a threshold distance of an estimated edge of the square. In some embodiments, the second machine learning model (e.g., 2^{nd} ML model 124) can filter off the holes near the edges as they could present for the microscope for stage movements.

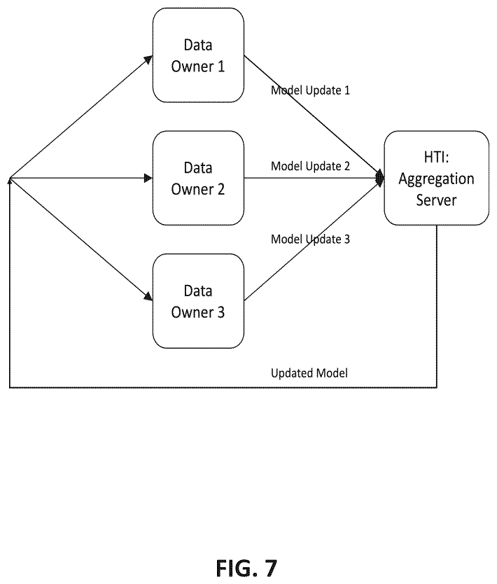

FIG. 7 illustrates an example of federated learning with multiple collaborators, in accordance with various embodiments. In some embodiments, the machine learning models implemented by computing system 120 (e.g., first, second, third ML models 122-126) may be broadcast to collaborators (e.g., data owner 1, data owner 2, data owner 3). Each collaborator (e.g., data owner 1, data owner 2, data owner 3) improve the models by training with their own data. The updated model parameters can be sent securely to an aggregation server in communication with or integrated within computing system 120. The aggregation server may aggregate the model parameters to build a combined model (for some or all of (e.g., first, second, third ML models 122-126), which can be provide improved results over the original model (prior to collaboration). The collaborators (e.g., data owner 1, data owner 2, data owner 3) do not share the data they used for retraining and retuning the original model. This will allow for larger collaboration as the collaborators do not have to share the data, which ensures privacy, IP protection and security.

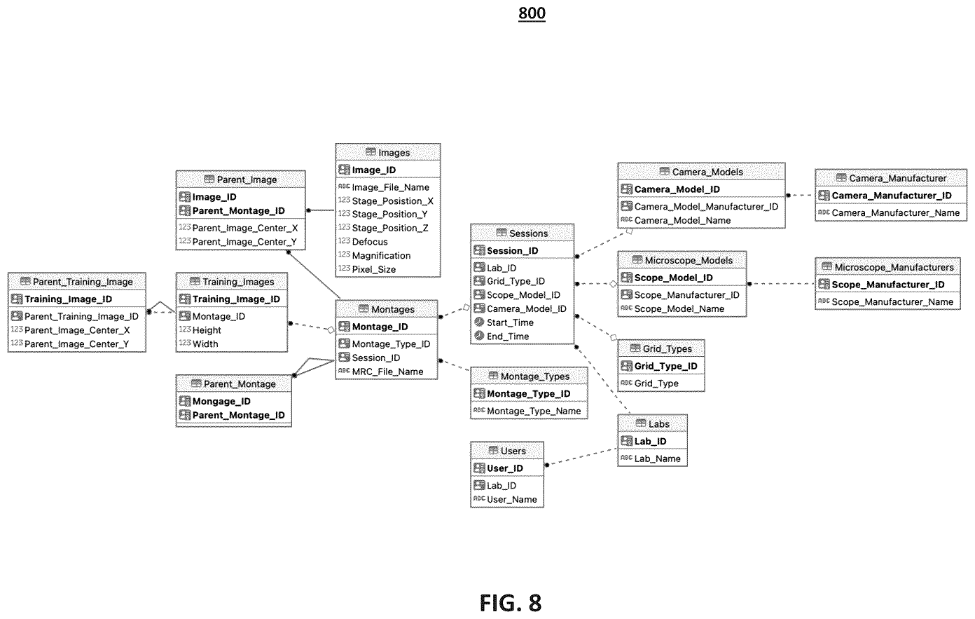

FIG. 8 illustrates an example database schematic 800, in accordance with various embodiments. Cryo-EM can generate several hundred GB s of data in several hundreds of files per run. Keeping the data in a searchable manner is critical for the user, who would want to identify where particular data originated from or which images have been obtained at a given target, and when. Database schematic 800 may be tuned for cryo-EM data collection and can be readily used by any of the database platforms (for example, Postgres).

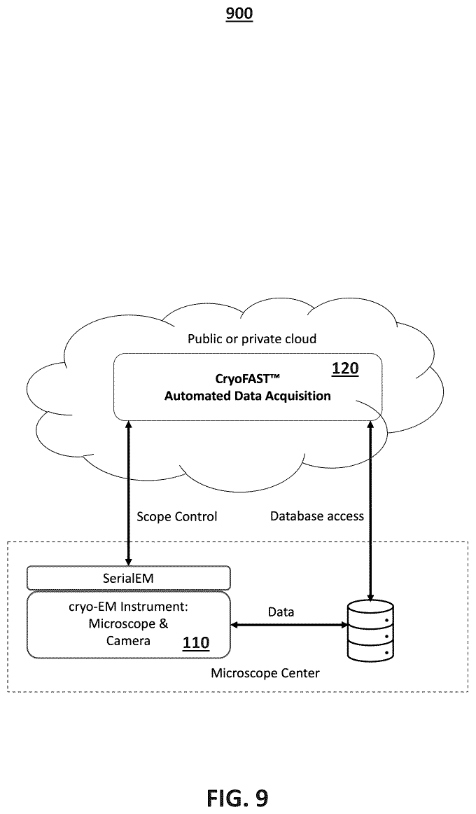

FIG. 9 illustrates an example cloud approach 900, in accordance with various embodiments. In some embodiments, cloud approach 900 can allow a user to operate computing system 120 (e.g., the CryoFAST software) from public cloud computing environment or from a private/enterprise cloud computing environment. In cloud approach 900, data capture and storage may reside on a client's local system (e.g., in microscope center) and may communicate securely with computing system 120 to implement the image analysis process.

FIG. 10 illustrates example micrographs 1000a-1030a and their corresponding Fourier Transform images 1000b-1030b for evaluating micrograph quality, in accordance with various embodiments. This approach can remove “junk” data ahead of any processing. This can improve the efficiency of processing the data downstream and possibly arrive at better resolution structures. As shown in FIG. 10, images 1000b-1030b of the Fourier Transforms (the concentric rings, representing various frequencies) have different characteristics for micrographs with various artifacts, defocus values, etc. A model will be trained to identify good Micrographs. This model will be used to infer the quality of the micrographs generated. In the illustrated example, Fourier transform image 1000b may represent image 1000a (e.g., a micrograph), which was captured in the spatial domain. Fourier transform image 1000b may represent an example of a Fourier transform of a “good micrograph.” On the other hand, Fourier transform images 1010b and 1030b may represent an example of a Fourier transform of a “bad micrograph.” Thus, images 1010a and 1030a may not be representative and therefore should not be used for downstream analysis and 3D reconstruction. Fourier transform image 1020b may represent another example of a Fourier transform of a micrograph (e.g., micrograph 1020a).

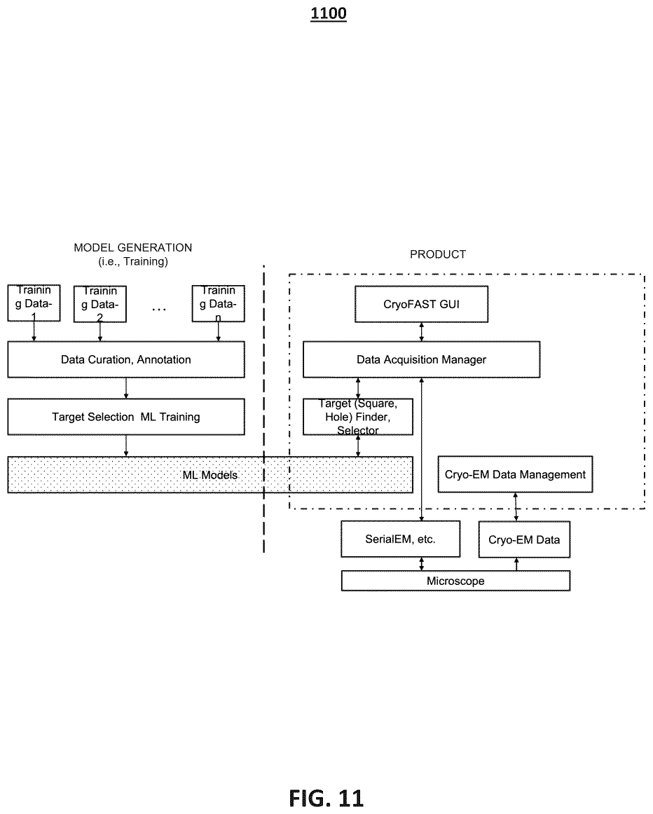

FIG. 11 illustrates an example architecture 1100 of system described herein, in accordance with various embodiments. Machine Learning models can be used during two phases: Training and Inference. During the training phase, data from several sources can be used to gain the diversity needed. The data may be pre-processed and annotated and used for training and generating the ML model. More training data can be utilized over time, and hence the trained model will become more efficient. During the inference phase, the ML model can used to assess and identify good targets (squares and holes), as shown in FIG. 5 and FIG. 6.

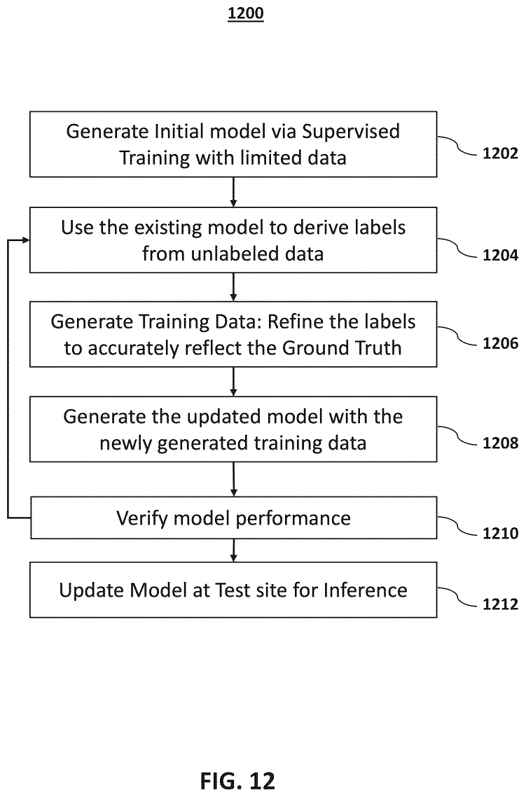

FIG. 12 illustrates a flowchart of an example method 1200 for training a machine learning via a semi-supervised approach, in accordance with various embodiments. In some embodiments, method 1200 may begin at step 1202. At step 1202, an initial model may be generated via a supervised-learning training process using limited data. At step 1204, the initial model may be used to derive labels from unlabeled image data. For example, a test image may be analyzed to determine a quality of squares depicted therein. The initial machine learning model may output a predicted label indicating whether each identified square is a “good square” or a “bad square,” as described above. At step 1206, training data may be generated by refining the derived labels to reflect ground truth information. In one or more examples, the ground truth information may be provided by a human-in-the-loop. For instance, first ML model 122 may predict that a given square depicted within an image is a “good square,” however a user reviewing the image may determine that this square is a “bad square.” Thus, the user can refine the derived label.

At step 1208, an updated version of the model may be generated using the newly generated training data (e.g., including the refined labels and predicted labels). At step 1210, the model's performance may be verified using test data. If the model's accuracy satisfies an accuracy condition, such as the accuracy being greater than or equal to a threshold accuracy level (e.g., 75% or greater accuracy, 85% or greater accuracy, 90% or greater accuracy, etc.), then the model may be considered verified. In some embodiments, steps 1204-1210 may repeat N times. Each iteration may result in a more accurate and broader model capable of analyzing more images. Upon the model's perform satisfying a threshold criteria and/or a number of iterations of steps 1204-1210 satisfying a threshold criteria (e.g., repeats N times), the updated model may be deployed for inference at step 1212. For example, first ML model 122, 2^{nd} ML model 124, and 3^{rd} ML model 126 may each be models that are capable of being used for inferences.

In some embodiments, method 1200 may be performed to train first ML model 122, 2^{nd} ML model 124, and/or 3^{rd} ML model 126. For each model, the contents depicted by the image data used during training may vary. For example, to train first ML model 122 using method 1200, the training data may comprise images of grids of squares. To train 2^{nd} ML model 124 using method 1200, the training data may comprise images of holes within a “good square.” To train 3^{rd} ML model 126 using method 1200, the training data may comprise images of “good holes.”

The notion of semi-supervised training is based on automatically annotating raw data and adjusting the labels for further training of the model. This method significantly improves productivity for training data preparation.

The automatic annotation will be an important tool for Federated Learning collaborators, as it makes collaboration practical.

FIG. 13 illustrates an example flowchart of a method 1300 for performing data analysis by analyzing a subset at a time and deciding on the next subset for analysis, in accordance with various embodiments. FIG. 13 illustrates how data processing can be more efficient by analyzing subsets of data at any given time. The subset analysis allows the user to choose the next subset based on the quality of the current set. A good set is likely to have adjacent good datasets. This simple method of data harvesting would allow for faster data processing, without the need for using the entire dataset to arrive at structures.

In some embodiments, method 1300 may begin at step 1302. At step 1302, data may be acquired. The data may include images depicting one or more squares or images depicting one or more holes (depending on whether first ML model 122 or second ML model 124 is being analyzed. At step 1304, a subset of squares of holes within the images may be chosen. The subset of squares or holes may be selected randomly or based on other factors. At step 1306, the data may be assessed. For example, the subset of squares may be analyzed using first ML model 122. The subset of holes may be analyzed using second ML model 124.

At step 1308, a determination may be made as to whether the data is good. For example, a determination may be made as to whether the squares within the subset of squares comprise “good squares” or “bad squares.” The determination may alternatively determine whether the holes within the subset of holes comprise “good holes” or “bad holes.” If, at step 1308, the data is determined to be good, then method 1300 may proceed to step 1310, where a subset of squares or holes nearby the subset of squares or holes may be chosen. In some embodiments, the nearby subset of squares/holes may be selected based on their proximity to the evaluated subset of squares/holes. In one or more examples, the subset of squares/holes may be selected randomly. If, however, at step 1308, it is determined that the data is not good (e.g., “bad squares,” “bad holes,” then method 1300 may proceed to step 1312. At step 1312, a subset of squares/holes not near the subset of squares/holes evaluated at step 1306 may be selected.

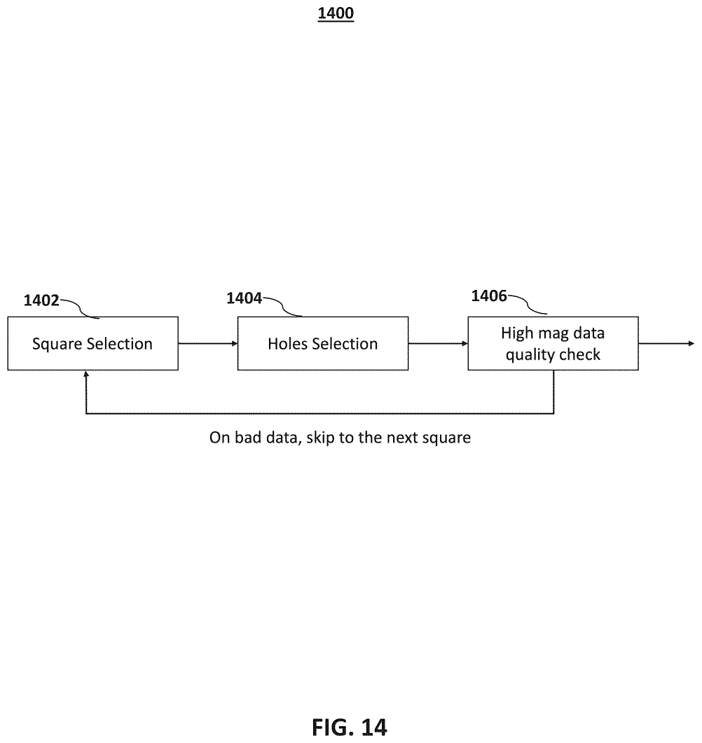

FIG. 14 illustrates an example flowchart of a method 1400 for selecting on-the-fly data acquisition targets based on a quality of the current data, in accordance with various embodiments. When the current data set does not show good quality (e.g., step 1312 of FIG. 13), it may be that the current target square is problematic. Thus, the data collection could be switched to the “next square” saving microscope time, and obtaining better quality data. For example, method 1400 may begin at step 1402, where a square may be selected. At step 1404, one or more holes within the selected square may be selected. At step 1406, one or more high-magnification images may be obtained and evaluated to determine whether the micrograph of the hole is “good.” If so, method 1400 may end. However, if the hole is “bad,” method 1400 may return to step 1402 where a new (next) square may be selected.

FIG. 15 illustrates an example computer system 1500. In particular embodiments, one or more computer systems 1500 perform one or more steps of one or more methods described or illustrated herein. In particular embodiments, one or more computer systems 1500 provide functionality described or illustrated herein. In particular embodiments, software running on one or more computer systems 1500 performs one or more steps of one or more methods described or illustrated herein or provides functionality described or illustrated herein. Particular embodiments include one or more portions of one or more computer systems 1500. Herein, reference to a computer system may encompass a computing device, and vice versa, where appropriate. Moreover, reference to a computer system may encompass one or more computer systems, where appropriate.

This disclosure contemplates any suitable number of computer systems 1500. This disclosure contemplates computer system 1500 taking any suitable physical form. As example and not by way of limitation, computer system 1500 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, or a combination of two or more of these. Where appropriate, computer system 1500 may include one or more computer systems 1500; be unitary or distributed; span multiple locations; span multiple machines; span multiple data centers; or reside in a cloud, which may include one or more cloud components in one or more networks. Where appropriate, one or more computer systems 1500 may perform without substantial spatial or temporal limitation one or more steps of one or more methods described or illustrated herein. As an example, and not by way of limitation, one or more computer systems 1500 may perform in real time or in batch mode one or more steps of one or more methods described or illustrated herein. One or more computer systems 1500 may perform at different times or at different locations one or more steps of one or more methods described or illustrated herein, where appropriate.

In particular embodiments, computer system 1500 includes a processor 1502, memory 1504, storage 1506, an input/output (I/O) interface 1508, a communication interface 1510, and a bus 1512. Although this disclosure describes and illustrates a particular computer system having a particular number of particular components in a particular arrangement, this disclosure contemplates any suitable computer system having any suitable number of any suitable components in any suitable arrangement.

In particular embodiments, processor 1502 includes hardware for executing instructions, such as those making up a computer program. As an example, and not by way of limitation, to execute instructions, processor 1502 may retrieve (or fetch) the instructions from an internal register, an internal cache, memory 1504, or storage 1506; decode and execute them; and then write one or more results to an internal register, an internal cache, memory 1504, or storage 1506. In particular embodiments, processor 1502 may include one or more internal caches for data, instructions, or addresses. This disclosure contemplates processor 1502 including any suitable number of any suitable internal caches, where appropriate. As an example, and not by way of limitation, processor 1502 may include one or more instruction caches, one or more data caches, and one or more translation lookaside buffers (TLBs). Instructions in the instruction caches may be copies of instructions in memory 1504 or storage 1506, and the instruction caches may speed up retrieval of those instructions by processor 1502. Data in the data caches may be copies of data in memory 1504 or storage 1506 for instructions executing at processor 1502 to operate on; the results of previous instructions executed at processor 1502 for access by subsequent instructions executing at processor 1502 or for writing to memory 1504 or storage 1506; or other suitable data. The data caches may speed up read or write operations by processor 1502. The TLBs may speed up virtual-address translation for processor 1502. In particular embodiments, processor 1502 may include one or more internal registers for data, instructions, or addresses. This disclosure contemplates processor 1502 including any suitable number of any suitable internal registers, where appropriate. Where appropriate, processor 1502 may include one or more arithmetic logic units (ALUs); be a multi-core processor; or include one or more processors 1502. Although this disclosure describes and illustrates a particular processor, this disclosure contemplates any suitable processor.

In particular embodiments, memory 1504 includes main memory for storing instructions for processor 1502 to execute or data for processor 1502 to operate on. As an example, and not by way of limitation, computer system 1500 may load instructions from storage 1506 or another source (such as, for example, another computer system 1500) to memory 1504. Processor 1502 may then load the instructions from memory 1504 to an internal register or internal cache. To execute the instructions, processor 1502 may retrieve the instructions from the internal register or internal cache and decode them. During or after execution of the instructions, processor 1502 may write one or more results (which may be intermediate or final results) to the internal register or internal cache. Processor 1502 may then write one or more of those results to memory 1504. In particular embodiments, processor 1502 executes only instructions in one or more internal registers or internal caches or in memory 1504 (as opposed to storage 1506 or elsewhere) and operates only on data in one or more internal registers or internal caches or in memory 1504 (as opposed to storage 1506 or elsewhere). One or more memory buses (which may each include an address bus and a data bus) may couple processor 1502 to memory 1504. Bus 1512 may include one or more memory buses, as described below. In particular embodiments, one or more memory management units (MMUs) reside between processor 1502 and memory 1504 and facilitate accesses to memory 1504 requested by processor 1502. In particular embodiments, memory 1504 includes random access memory (RAM). This RAM may be volatile memory, where appropriate This RAM may be dynamic RAM (DRAM) or static RAM (SRAM). Moreover, where appropriate, this RAM may be single-ported or multi-ported RAM. This disclosure contemplates any suitable RAM. Memory 1504 may include one or more memories 1504, where appropriate. Although this disclosure describes and illustrates particular memory, this disclosure contemplates any suitable memory.

In particular embodiments, storage 1506 includes mass storage for data or instructions. As an example, and not by way of limitation, storage 1506 may include a hard disk drive (HDD), a floppy disk drive, flash memory, an optical disc, a magneto-optical disc, magnetic tape, or a Universal Serial Bus (USB) drive or a combination of two or more of these. Storage 1506 may include removable or non-removable (or fixed) media, where appropriate. Storage 1506 may be internal or external to computer system 1500, where appropriate. In particular embodiments, storage 1506 is non-volatile, solid-state memory. In particular embodiments, storage 1506 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 1506 taking any suitable physical form. Storage 1506 may include one or more storage control units facilitating communication between processor 1502 and storage 1506, where appropriate. Where appropriate, storage 1506 may include one or more storages 1506. Although this disclosure describes and illustrates particular storage, this disclosure contemplates any suitable storage.

In particular embodiments, I/O interface 1508 includes hardware, software, or both, providing one or more interfaces for communication between computer system 1500 and one or more I/O devices. Computer system 1500 may include one or more of these I/O devices, where appropriate. One or more of these I/O devices may enable communication between a person and computer system 1500. As an example, and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 1508 for them. Where appropriate, I/O interface 1508 may include one or more device or software drivers enabling processor 1502 to drive one or more of these I/O devices. I/O interface 1508 may include one or more I/O interfaces 1508, where appropriate. Although this disclosure describes and illustrates a particular I/O interface, this disclosure contemplates any suitable I/O interface.

In particular embodiments, communication interface 1510 includes hardware, software, or both providing one or more interfaces for communication (such as, for example, packet-based communication) between computer system 1500 and one or more other computer systems 1500 or one or more networks. As an example, and not by way of limitation, communication interface 1510 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 1510 for it. As an example, and not by way of limitation, computer system 1500 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 1500 may communicate with a wireless PAN (WPAN) (such as, for example, a BLUETOOTH WPAN or ultra-wideband WPAN), a WI-FI network, a WI-MAX network, a cellular telephone network (such as, for example, a Global System for Mobile Communications (GSM) network), or other suitable wireless network or a combination of two or more of these. Computer system 1500 may include any suitable communication interface 1510 for any of these networks, where appropriate. Communication interface 1510 may include one or more communication interfaces 1510, where appropriate. Although this disclosure describes and illustrates a particular communication interface, this disclosure contemplates any suitable communication interface.

In particular embodiments, bus 1512 includes hardware, software, or both coupling components of computer system 1500 to each other. As an example and not by way of limitation, bus 1512 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 1512 may include one or more buses 1512, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, any reference herein to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

### EXAMPLE EMBODIMENTS

Embodiments disclosed herein may include:
1. A method identifying biological structures depicted within an image captured using a cryogenic electron microscopy, the method comprising: receiving a first image montage comprising first images captured at a first magnification level, the first image montage depicting a cryogenic electron microscopy grid comprising a plurality of cryogenic electron microscopy grid units; detecting, using a first machine learning model, one or more cryogenic electron microscopy grid units that satisfy a first quality condition based on the first image montage; for each of the one or more cryogenic electron microscopy grid units: receiving a second image montage comprising second images of the cryogenic electron microscopy grid unit captured at a second magnification level; and detecting, using a second machine learning model, one or more apertures within the cryogenic electron microscopy grid unit that satisfy a second quality condition based on the second image montage; for each of the one or more apertures: receiving one or more images depicting at least one of ice or a biological structure suspended within the aperture captured at a third magnification level; generating a Fourier transformation of each of the one or more images; and identifying, using a third machine learning model, at least one image depicting the biological structure from the one or more images based on the Fourier transformation of each of the one or more images, wherein the at least one image captured at the third magnification level is used for generating a 3D representation of the biological structure.
2. The method of embodiment 1, wherein the first magnification level is less than the second magnification level, and the second magnification level is less than the third magnification level.
3. The method of any one of embodiments 1-2, wherein the first image montage, the second image montage, and the one or more images are captured using a cryogenic electron microscopy.
4. The method of embodiment 3, further comprising: generating a first instruction to set a magnification level of the cryogenic electron microscopy to the first magnification level prior to the first image montage being captured; generating a second instruction to set the magnification level of the cryogenic electron microscopy to the second magnification level prior to the second image montage being captured; and generating a third instruction to set the magnification level of the cryogenic electron microscopy to the third magnification level prior to the one or more images being captured.
5. The method of any one of embodiments 1-4, further comprising: obtaining a first plurality of training images captured at the first magnification level, wherein the first plurality of training images each depict a cryogenic electron microscopy grid comprising a plurality of cryogenic electron microscopy grid units, and wherein each of the plurality of training images includes metadata indicating a location and bounding box associated with each of the plurality of cryogenic electron microscopy grid units; and training the first machine learning model to identify cryogenic electron microscopy grid units based on the first plurality of training images.
6. The method of embodiment 5, wherein the first machine learning model is configured to at least one of: determine a predicted location of a center of each of the cryogenic electron microscopy grid units within a corresponding training image from the first plurality of training images; or determine a predicted boundary of each of the cryogenic electron microscopy grid units within a corresponding training image from the first plurality of training images.
7. The method of embodiment 5 or 6, wherein training the first machine learning model comprises: inputting each of the first plurality of training images to the first machine learning model to obtain an output of at least one of: a predicted location of a center of each of the cryogenic electron microscopy grid units, or a predicted boundary of each of the cryogenic electron microscopy grid units; generating a comparison of the at least one of the predicted location or the predicted boundary with a predetermined location of the center of each of the cryogenic electron microscopy grid units or a predetermined boundary of each of the cryogenic electron microscopy grid units; and updating a first set of parameters of the first machine learning model based on the comparisons.
8. The method of any one of embodiments 1-7, wherein detecting the one or more cryogenic electron microscopy units that satisfy the first quality condition comprises: for each of the plurality of cryogenic electron microscopy grid units, generating, using the first machine learning model, a first score indicating a quality of the cryogenic electron microscopy grid units; and selecting, from the plurality of cryogenic electron microscopy grid units, the one or more cryogenic electron microscopy grid units having a first score that is greater than or equal to a first quality threshold score.
9. The method of any one of embodiments 1-8, further comprising: obtaining a second plurality of training images captured at the second magnification level, wherein the second plurality of training images each depict a cryogenic electron microscopy grid unit comprising a plurality of candidate apertures, and wherein each of the second plurality of training images includes metadata indicating a location and bounding box associated with each of the plurality of candidate apertures; and training the second machine learning model to identify apertures based on the second plurality of training images.
10. The method of embodiment 9, wherein the second machine learning model is configured to at least one of: determine a predicted location of a center of each of the apertures within a corresponding training image from the second plurality of training images; or determine a predicted boundary of each of the apertures within a corresponding training image from the second plurality of training images.
11. The method of embodiment 9 or 10, wherein training the second machine learning model comprises: inputting each of the second plurality of training images to the second machine learning model to obtain an output of at least one of: a predicted location of a center of each of the apertures, or a predicted boundary of each of the apertures; generating a comparison of the at least one of the predicted location or the predicted boundary with a predetermined location of the center of each of the apertures or a predetermined boundary of each of the apertures; and updating a second set of parameters of the second machine learning model based on the comparisons.
12. The method of any one of embodiments 1-11, wherein detecting the one or more apertures that satisfy the second quality condition comprises: inputting the second images into the trained second machine learning model to obtain a second score indicating a likelihood that at least one of a biological structure suspended within each of a plurality of apertures depicted by the second images; and selecting, from the plurality of apertures, the one or more apertures having a second score that is greater than or equal to a second quality threshold score.
13. The method of any one of embodiments 1-12, further comprising: obtaining a third plurality of training images captured at the third magnification level, wherein the third plurality of training images each depict an aperture from the one or more apertures, wherein each of the third plurality of training images comprises a first label or a second label indicating whether the training image depicts a positive reference aperture or a negative reference aperture; generating Fourier transform images representing a Fourier transform of each of the third plurality of training images; for each of the Fourier transform images: calculating a third score indicating a similarity between the Fourier transform image and an image of a Fourier transform of an image of a positive reference aperture.
14. The method of any one of embodiments 1-13, wherein identifying the at least one image comprises: inputting the Fourier transform of each of the one or more images into the trained third machine learning model to obtain a third score indicating a similarity between the Fourier transform and an image of a Fourier transform of an image of a positive reference aperture; and selecting, from the plurality of apertures, the one or more apertures having a second score that is greater than or equal to a second quality threshold score, wherein the at least one image is selected based on the third score calculated for the at least one image being greater than or equal to a third quality threshold score.
15. The method of any one of embodiments 1-14, further comprising: generating the 3D representation of a biological structure depicted by the at least one image.
16. The method of any one of embodiments 1-15, further comprising: performing one or more assays based on the 3D representation of the biologic structure for drug discovery evaluations.
17. The method of any one of embodiments 1-16, wherein detecting the one or more cryogenic electron microscopy grid units comprises: selecting a first cryogenic electron microscopy grid unit of the plurality of cryogenic electron microscopy grid units; calculating a first score for the first cryogenic electron microscopy grid unit; determining that the first score for the first cryogenic electron microscopy grid unit is less than a first threshold score; selecting a second cryogenic electron microscopy grid unit of the plurality of cryogenic electron microscopy grid units, wherein the first cryogenic electron microscopy grid unit is located adjacent to the second cryogenic electron microscopy grid unit on the cryogenic electron microscopy grid; calculating a second score for the second cryogenic electron microscopy grid unit, wherein the second cryogenic electron microscopy grid unit is selected from the plurality of cryogenic electron microscopy grid units based on the second score being greater than or equal to the first threshold score.
18. The method of any one of embodiments 1-18, wherein the first machine learning model, the second machine learning model, and the third machine learning model are implemented using a convolutional neural network.
19. A system for identifying biological structures depicted within an image captured using a cryogenic electron microscopy, comprising: memory storing computer-program instructions; and one or more processors configured to execute the computer-program instructions to cause the one or more processors to perform the method of any one of embodiments 1-18.
20. A non-transitory computer-readable medium storing computer program instructions that, when executed, effectuate operations comprising the method of any one of embodiments 1-18.

What we claim is:

1. A method identifying biological structures depicted within an image captured using a cryogenic electron microscopy, the method comprising:
receiving a first image montage comprising first images captured at a first magnification level, the first image montage depicting a cryogenic electron microscopy grid comprising a plurality of cryogenic electron microscopy grid units;
detecting, using a first machine learning model, one or more cryogenic electron microscopy grid units that satisfy a first quality condition based on the first image montage; and
for each of the one or more cryogenic electron microscopy grid units:
receiving a second image montage comprising second images of the cryogenic electron microscopy grid unit captured at a second magnification level;
detecting, using a second machine learning model, one or more apertures within the cryogenic electron microscopy grid unit that satisfy a second quality condition based on the second image montage; and
for each of the one or more apertures:
receiving one or more images depicting at least one of ice or a biological structure suspended within the aperture captured at a third magnification level;
generating a Fourier transformation of each of the one or more images; and
identifying, using a third machine learning model, at least one image depicting the biological structure from the one or more images based on the Fourier transformation of each of the one or more images, wherein the at least one image captured at the third magnification level is used for generating a 3D representation of the biological structure.

2. The method of claim 1, wherein the first magnification level is less than the second magnification level, and the second magnification level is less than the third magnification level.

3. The method of claim 1, wherein the first image montage, the second image montage, and the one or more images are captured using a cryogenic electron microscopy.

4. The method of claim 3, further comprising:
generating a first instruction to set a magnification level of the cryogenic electron microscopy to the first magnification level prior to the first image montage being captured;
generating a second instruction to set the magnification level of the cryogenic electron microscopy to the second magnification level prior to the second image montage being captured; and
generating a third instruction to set the magnification level of the cryogenic electron microscopy to the third magnification level prior to the one or more images being captured.

5. The method of claim 1, further comprising:
obtaining a first plurality of training images captured at the first magnification level, wherein the first plurality of training images each depict a cryogenic electron microscopy grid comprising a plurality of cryogenic electron microscopy grid units, and wherein each of the first plurality of training images includes metadata indicating a location and bounding box associated with each of the plurality of cryogenic electron microscopy grid units; and
training the first machine learning model to identify cryogenic electron microscopy grid units based on the first plurality of training images.

6. The method of claim 5, wherein the first machine learning model is configured to at least one of:
determine a predicted location of a center of each of the cryogenic electron microscopy grid units within a corresponding training image from the first plurality of training images; or
determine a predicted boundary of each of the cryogenic electron microscopy grid units within a corresponding training image from the first plurality of training images.

7. The method of claim 5, wherein training the first machine learning model comprises:
inputting each of the first plurality of training images to the first machine learning model to obtain an output of at least one of:
a predicted location of a center of each of the cryogenic electron microscopy grid units, or
a predicted boundary of each of the cryogenic electron microscopy grid units;
generating a comparison of the at least one of the predicted location or the predicted boundary with a predetermined location of the center of each of the cryogenic electron microscopy grid units or a predetermined boundary of each of the cryogenic electron microscopy grid units; and
updating a first set of parameters of the first machine learning model based on the comparisons.

8. The method of claim 1, wherein detecting the one or more cryogenic electron microscopy grid units that satisfy the first quality condition comprises:
for each of the plurality of cryogenic electron microscopy grid units, generating, using the first machine learning model, a first score indicating a quality of the cryogenic electron microscopy grid units; and
selecting, from the plurality of cryogenic electron microscopy grid units, the one or more cryogenic electron microscopy grid units having a first score that is greater than or equal to a first quality threshold score.

9. The method of claim 1, further comprising:
obtaining a second plurality of training images captured at the second magnification level, wherein the second plurality of training images each depict a cryogenic electron microscopy grid unit comprising a plurality of candidate apertures, and wherein each of the second plurality of training images includes metadata indicating a location and bounding box associated with each of the plurality of candidate apertures; and
training the second machine learning model to identify apertures based on the second plurality of training images.

10. The method of claim 9, wherein the second machine learning model is configured to at least one of:
determine a predicted location of a center of each of the apertures within a corresponding training image from the second plurality of training images; or
determine a predicted boundary of each of the apertures within a corresponding training image from the second plurality of training images.

11. The method of claim 9, wherein training the second machine learning model comprises:
inputting each of the second plurality of training images to the second machine learning model to obtain an output of at least one of:
a predicted location of a center of each of the apertures, or
a predicted boundary of each of the apertures;
generating a comparison of the at least one of the predicted location or the predicted boundary with a predetermined location of the center of each of the apertures or a predetermined boundary of each of the apertures; and
updating a second set of parameters of the second machine learning model based on the comparisons.

12. The method of claim 1, wherein detecting the one or more apertures that satisfy the second quality condition comprises:
inputting the second images into the trained second machine learning model to obtain a second score indicating a likelihood that at least one of a biological structure is suspended within each of a plurality of apertures depicted by the second images; and
selecting, from the plurality of apertures, the one or more apertures having a second score that is greater than or equal to a second quality threshold score.

13. The method of claim 1, further comprising:
obtaining a third plurality of training images captured at the third magnification level, wherein the third plurality of training images each depict an aperture from the one or more apertures, wherein each of the third plurality of training images comprises a first label or a second label indicating whether the training image depicts a positive reference aperture or a negative reference aperture;
generating Fourier transform images representing a Fourier transform of each of the third plurality of training images; and
for each of the Fourier transform images:
calculating a third score indicating a similarity between the Fourier transform image and an image of a Fourier transform of an image of a positive reference aperture.

14. The method of claim 1, wherein identifying the at least one image comprises:
inputting the Fourier transform of each of the one or more images into the trained third machine learning model to obtain a third score indicating a similarity between the Fourier transform and an image of a Fourier transform of an image of a positive reference aperture; and
selecting, from a plurality of apertures, the one or more apertures having a second score that is greater than or equal to a second quality threshold score, wherein the at least one image is selected based on the third score calculated for the at least one image being greater than or equal to a third quality threshold score.

15. The method of claim 1, further comprising:
generating the 3D representation of a biological structure depicted by the at least one image.

16. The method of claim 1, further comprising:
performing one or more assays based on the 3D representation of the biological structure for drug discovery evaluations.

17. The method of claim 1, wherein detecting the one or more cryogenic electron microscopy grid units comprises:
selecting a first cryogenic electron microscopy grid unit of the plurality of cryogenic electron microscopy grid units;
calculating a first score for the first cryogenic electron microscopy grid unit;
determining that the first score for the first cryogenic electron microscopy grid unit is less than a first threshold score;
selecting a second cryogenic electron microscopy grid unit of the plurality of cryogenic electron microscopy grid units, wherein the first cryogenic electron microscopy grid unit is located adjacent to the second cryogenic electron microscopy grid unit on the cryogenic electron microscopy grid; and
calculating a second score for the second cryogenic electron microscopy grid unit, wherein the second cryogenic electron microscopy grid unit is selected from the plurality of cryogenic electron microscopy grid units based on the second score being greater than or equal to the first threshold score.

18. The method of claim 1, wherein the first machine learning model, the second machine learning model, and the third machine learning model are implemented using a convolutional neural network.

19. A system for identifying biological structures depicted within an image captured using a cryogenic electron microscopy, comprising:
memory storing computer-program instructions; and
one or more processors configured to execute the computer-program instructions to cause the one or more processors to:
receiving a first image montage comprising first images captured at a first magnification level, the first image montage depicting a cryogenic electron microscopy grid comprising a plurality of cryogenic electron microscopy grid units;
detecting, using a first machine learning model, one or more cryogenic electron microscopy grid units that satisfy a first quality condition based on the first image montage; and
for each of the one or more cryogenic electron microscopy grid units:
receiving a second image montage comprising second images of the cryogenic electron microscopy grid unit captured at a second magnification level;
detecting, using a second machine learning model, one or more apertures within the cryogenic electron microscopy grid unit that satisfy a second quality condition based on the second image montage; and
for each of the one or more apertures:
receiving one or more images depicting at least one of ice or a biological structure suspended within the aperture captured at a third magnification level;
generating a Fourier transformation of each of the one or more images; and
identifying, using a third machine learning model, at least one image depicting the biological structure from the one or more images based on the Fourier transformation of each of the one or more images,
wherein the at least one image captured at the third magnification level is used for generating a 3D representation of the biological structure.

20. A non-transitory computer-readable medium storing computer program instructions that, when executed, effectuate operations comprising:
receiving a first image montage comprising first images captured at a first magnification level, the first image montage depicting a cryogenic electron microscopy grid comprising a plurality of cryogenic electron microscopy grid units;
detecting, using a first machine learning model, one or more cryogenic electron microscopy grid units that satisfy a first quality condition based on the first image montage; and
for each of the one or more cryogenic electron microscopy grid units:
receiving a second image montage comprising second images of the cryogenic electron microscopy grid unit captured at a second magnification level;
detecting, using a second machine learning model, one or more apertures within the cryogenic electron microscopy grid unit that satisfy a second quality condition based on the second image montage; and
for each of the one or more apertures:
receiving one or more images depicting at least one of ice or a biological structure suspended within the aperture captured at a third magnification level;
generating a Fourier transformation of each of the one or more images; and
identifying, using a third machine learning model, at least one image depicting the biological structure from the one or more images based on the Fourier transformation of each of the one or more images, wherein the at least one image captured at the third magnification level is used for generating a 3D representation of the biological structure.
